(19) United States
(12) Patent Application Publication
(10) Pub. No.: US 2011/0140691 A1
(43) Pub. Date: Jun. 16, 2011

(54) NON-DESTRUCTIVE DETERMINATION OF MAGNETIC PERMEABILITY TENSOR IN MATERIALS OF ARBITRARY SHAPE

(75) Inventor: George Roy, Manotick (CA)

(73) Assignee: Her Majesty The Queen In Right Of Canada as represented by the Minister of Natural Resources, Ottawa (CA)

(21) Appl. No.: 12/638,473

(22) Filed: Dec. 15, 2009

(51) Int. Cl. G01R 33/12

(52) U.S. Cl. 324/228

(57) ABSTRACT

A method of non-destructive determination of a local magnetic permeability tensor of a material comprises testing by X-ray diffraction on a first surface to identify and measure any surface stress in the material; performing a calibration test using magnetostriction to identify any effect of any determined stress; subjecting the material to a magnetic field having a strength H and measuring a field of induction B on the surface at the selected location and repeating this step by using gradual increases of H until a saturated value is determined for B, to determine a distribution of magnetic domains at the selected location; repeating the determinations of saturated values for B at additional locations on each selected surface of the material; and using the saturated values and distribution of magnetic domains to derive the magnetic permeability tensor. The non-destructive method provides increased accuracy for stressed or unstressed materials of arbitrary shape.

### FIELD OF THE INVENTION

This invention relates to methods of determination of magnetic permeability of materials, and in particular to a method of non-destructive determination of a local magnetic permeability tensor in stressed or unstressed materials of arbitrary shape.

### BACKGROUND OF THE INVENTION

Methods of determination of the magnetic permeability of materials are known. However, these are destructive to the material, in that these known methods involve the removal of a sample from the material. The usual method for this determination is to remove a ring of the material, known as a Rowland ring, around which primary and secondary coils are wound up, and connected to a histeresigraph, which identifies and records the resulting values when a current is passed through the coils to generate a magnetic field around the ring.

For materials which are isotropic, the known methods can be expected to be reasonably accurate, but they are destructive to the material. Furthermore, for larger samples, in addition to being destructive, the known methods are complex and time consuming.

However, for materials which are magnetically anisotropic, in addition to being destructive, the accuracy of the methods is seriously compromised in that the known methods are only capable of providing an average value of one component of the permeability tensor over a large volume of material, and usually in the axial direction of the ring.

In addition, any stress in the subject material will further invalidate the obtained results, which will be at best approximate if the stress is substantially smaller than the σ_{y}=0.2%—yield strength of the material. If the stress is comparable to a substantial fraction of σ_{y}, the measurements will not be representative of the local components of the permeability tensor at all.

The materials to be tested can be subjected to two important types of stress which can result in dimensional changes, namely: 1) (external or internal, known also as residual) mechanical stress, and, 2) Villari stress, resulting from the inherent property known as magnetostriction. The latter one arises from an application of a magnetic field leading to changes in the boundaries between magnetic domains and rotations of the domains. The known methods of determining magnetic permeability do not take these stress effects into account.

Still further, histeresigraphs used for the known methods require an alternating current (AC), and measurements with histeresigraphs are very time-consuming. However, AC can only be used effectively for diamagnetic and paramagnetic materials, where the relation between the magnetic induction vector B and the field strength vector H is essentially linear, as discussed in more detail below.

Therefore, what is required is an accurate method of determining the magnetic permeability of a greater range of materials, both isotropic or anisotropic, which does not require any destruction of the material, is able to compensate for the effect of any stress in the materials, can be applied to small local areas of a larger material, and in particular is suitable for magnetic materials in all their forms, most particularly iron, nickel, cobalt and gadolinium, as well as their alloys.

It has been found that if any stress in the material, arising either from its inherent property, i.e. external and/or internal mechanical stress, or magnetostriction, is identified and measured by X-ray diffraction method, this can be taken into account, before the material is subjected to a magnetic field with a series of increases in field strength, to obtain the measurements required to determine the magnetic permeability. Further, the field of induction can thus be measured on the surface of the material in order to determine the magnetic permeability at specific locations, without any need for the removal of a sample, and thus with no destructive effect on the material. The resulting permeability tensor determined by the method has significantly higher accuracy for all types of materials, particularly anisotropic materials, and most particularly the ferromagnetic materials. A further advantage of this method of the invention is that substantial time savings are obtained as compared to known methods, in particular taking measurements with histeresigraphs.

The invention therefore seeks to provide a method of non-destructive determination of a local magnetic permeability tensor of a material having a plurality of selected surfaces, the method comprising

(a) testing by X-ray diffraction on a first of the selected surfaces to identify and measure any surface stress in the material;

(b) performing a calibration test using magnetostriction to identify any effect of any stress determined in step (a);

(c) subjecting the material to a magnetic field having a strength H and measuring a field of induction B on the surface at the selected location;

(d) repeating step (c) by using gradual increases of the field strength H until a saturated value is determined for B;

(e) determining a distribution of magnetic domains at the selected location; and

(f) repeating steps (c), (d) and (e) at additional selected locations on each selected surface of the material; and

(g) using the values determined in step (d) and the distribution determined in step (e) to derive the magnetic permeability tensor.

Preferably, step (b) comprises

(b.1) applying a magnetic field through an induction coil powered by a DC-current, measuring the resultant changes of shape of the material using X-ray diffraction to obtain a first measurement;
(b.2) varying the DC-current and repeating step (b.1); and
(b.3) repeating steps (b.1) and (b.2) until a stress-magnetic field strength line is obtained.

Preferably, the measuring in steps (c) and (d) is performed using a Gaussmeter, more preferably with at least one Hall sensor.

Preferably, the magnetic field in steps (c) and (d) is created by applying a DC current to a multi-turn coil, which preferably has a substantially conical configuration, to focus field B.

The determining of the distribution of magnetic domains in step (e) can be performed by any suitable means, but preferably comprises a numerical modelling method, more preferably by a numerical modelling method selected from a finite element method, a boundary element method, a finite difference method and a finite volume method.

As discussed above, the method can be used on a very broad variety of materials having magnetic properties, including liquid materials. In particular, as discussed further below, the material can comprise human blood, the magnetic permeability of which provides a reliable indicator of the level of haemoglobin.

### BRIEF DESCRIPTION OF THE DRAWINGS

The invention will now be described in relation to the accompanying drawings, in which

FIG. 1 shows the use of X-ray diffraction to determine stress in a subject material;

FIG. 2 is a schematic representation of the measurement method of the invention in relation to a three-dimensional object; and

FIG. 3 shows the variation of the magnetic induction vector in response to changing magnetic field strengths for ferromagnetic materials in comparison with diamagnetic and paramagnetic materials.

### DETAILED DESCRIPTION

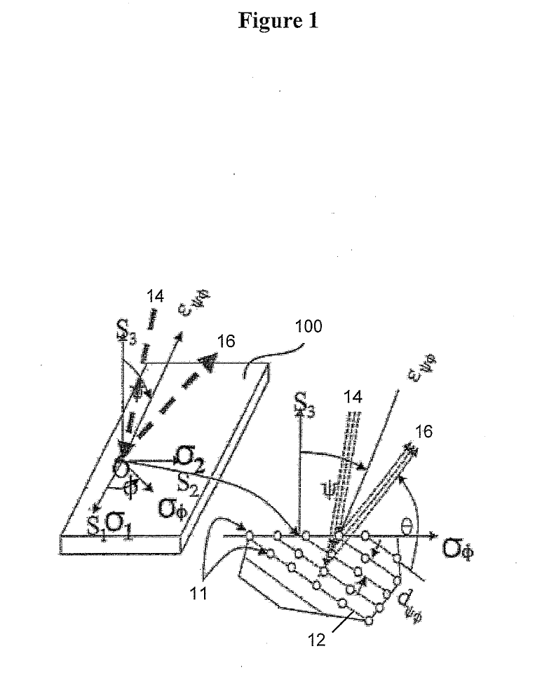

Referring first to FIG. 1, the first step in the method of the invention is to determine whether there is stress in the subject material, so that compensation for this factor can be made in the determination of the magnetic permeability of the material. The stress is measured at a selected surface of the material, by an X-ray diffraction process, using known equipment. The figure shows the measurement of strain at the selected location at which the incident X-ray beam is shown as 14 and the diffracted X-ray beam as 16. The principal stress components are shown as σₗ and σ₂, in directions S₁ and S₂, respectively, at the location O of strain measurement ε_{ψφ} on the surface 100, with atomic planes 12 and their spacing d_{ψφ}, such that

$$\frac{{d}_{ψϕ} - {d}_{0}}{{d}_{0}}$$

denotes the strain ε_{ψφ} measured in the horizontal φ-direction along the σ_{φ}-stress direction, and at the ψ-angle from the normal σ₁₁×σ₂₂ to the material surface formed by the principal directions σ₁₁ and σ₂₂; and d_{ψφ} denotes the spacing of (imaginary) atomic planes 12 (dashed lines) of atoms 11 in the ψ direction from the original d₀ spacing.

When the stress, if any, has been identified and quantified, its effect can be calibrated from magnetostriction at the selected location, so that the accuracy of the subsequent determination of permeability will not be adversely affected by the existence of stress.

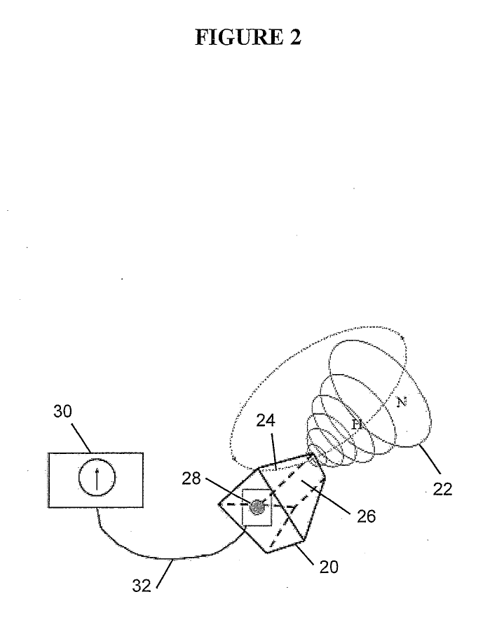

Referring now to FIG. 2, the material 20 is then subjected to a magnetic field by the use of known means, such as a multi-turn coil 22, which is directed at the selected location 24 in the selected surface 26. The multi-turn coil 22 is energized with a direct current, to provide a magnetic field of initial strength H, and the field of induction B is measured at the selected location 24 (or any other one close to it, as shown in the figure) by any suitable means, such as Hall sensor 28, connected, for example by cable 32, to suitable equipment, such as a Voltmeter or a Gaussmeter 30, which is tuned to detect the Quantum Hall effect. Gradual increases are made in the strength H, and corresponding measurements of B recorded, until a situation is reached at which a saturated value is determined for B.

At the same time, the distribution of the magnetic domains is determined, by any suitable method, preferably by a numerical modelling technique such as the finite element method or the boundary element method. The use of numerical modelling avoids the problems arising from the fact that the magnetic material changes as a result of the internal distribution of the induced magnetic field inside it. Other methods are known, such as methods using quantum mechanical and density functional theories, but these are significantly more complex than numerical modelling.

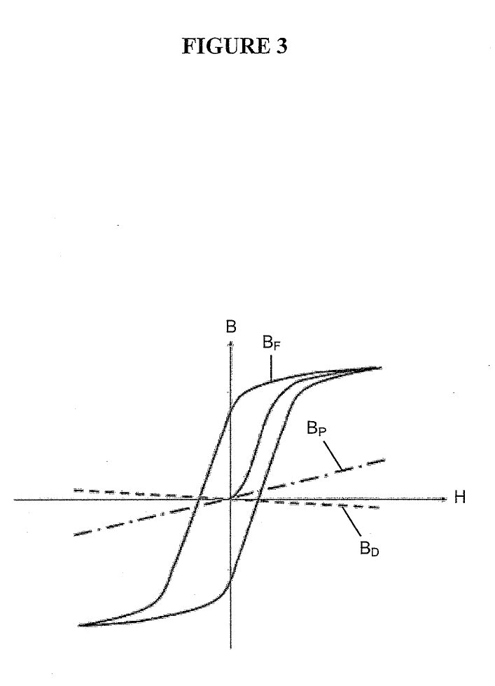

Referring now to FIG. 3, the relationship of the magnetic induction vector B and the filed strength vector H is shown for various materials. In the case of diamagnetic materials and paramagnetic materials, this relationship is essentially linear, and can be expressed as B=μH, where μ, which is magnetic permeability, and for isotropic materials is a constant. However, for anisotropic materials, μ is a tensor. For ferromagnetic materials, the relationship between B and H is non-linear, and μ is usually a non-linear function of H, i.e. B=μ(H) H, as shown in FIG. 3. Because of this non-linear variation, the permeability of ferromagnetic materials cannot be accurately determined by the known methods using AC current, such as a histeresigraph. The method of the invention, when using DC, is thus particularly useful for the ferromagnetic materials. FIG. 3 shows the variation of the magnetic induction vector B in response to changing magnetic strength field H for ferromagnetic materials B_{F} in comparison with diamagnetic materials B_{D} and paramagnetic materials B_{P}.

Thereafter, the same steps are repeated for each surface to be examined, i.e. each surface is subjected to a magnetic field of gradually increasing strengths H, until the saturation values of B are reached.

From the results of each determination from the H and B measurements, the magnetic permeability tensor can be determined.

In addition to the uses of the invention, which are apparent from the discussion above, the method of the invention can be used to measure magnetic permeability of materials in all kinds of stress situations. For example, the method can be used for measurements relating to materials such as the magnetic fibres in aircraft magnetic circuits, the magnetic components in all manner of electromagnetic applications, such as automotive electromagnetic circuits. The method of the invention can enable the direct measurement of stress through strain at the crystal (grain) level in magnetic materials.

Further, the method of the invention can be used in the design and production of highly directional anisotropic magnets, or miniature magnetostrictive sensors to measure stress in any material through external bonding.

In addition, the method of the invention can be used to measure the ability of magnetic materials to absorb hydrogen, and to measure the amount of hydrogen stored in hydrides.

Further, the method of the invention can be used to measure the magnetic permeability of hematite (iron oxide) present in human blood, to provide a reliable indicator of the level of haemoglobin, and the ability to identify the presence and quantity of small magnetic domains in blood provides a significant feature in the ongoing development of Magnetic Resonance Imaging (MRI) processes, where Wavelet Analysis can be used additionally to enhance the presence of features unnoticed even by experts in the field. Of course, in this application, no X-ray (diffraction type) measurements would be carried out, for health reasons, although this can be determined numerically through quantum mechanical modeling, the Virial theorem, or measured using scanning electron microscope, if necessary, to determine the stress tensor through the strain tensor at the atomistic-molecular level.

1. A method of non-destructive determination of a local magnetic permeability tensor of a material having a plurality of selected surfaces, the method comprising
(a) testing by X-ray diffraction on a first of the selected surfaces to identify and measure any surface stress in the material;
(b) performing a calibration test using magnetostriction to identify any effect of any stress determined in step (a);
(c) subjecting the material to a magnetic field having a strength H and measuring a field of induction B on the surface at the selected location;
(d) repeating step (c) by using gradual increases of the field strength H until a saturated value is determined for B;
(e) determining a distribution of magnetic domains at the selected location; and
(f) repeating steps (c), (d) and (e) at additional selected locations on each selected surface of the material; and
(g) using the values determined in step (d) and the distribution determined in step (e) to derive the magnetic permeability tensor.

2. A method according to claim 1 wherein step (b) comprises
(b.1) applying a magnetic field through an induction coil powered by a DC-current, measuring the resultant changes of shape of the material using X-ray diffraction to obtain a first measurement;
(b.2) varying the DC-current and repeating step (b.1); and
(b.3) repeating steps (b.1) and (b.2) until a stress-magnetic field strength line is obtained.

3. A method according to claim 1, wherein the measuring in steps (c) and (d) is performed using a Gaussmeter.

4. A method according to claim 3, wherein the measuring in steps (c) and (d) is performed using a Gaussmeter with at least one Hall sensor.

5. A method according to claim 1 wherein the magnetic field in steps (c) and (d) is created by applying a DC current to a multi-turn coil.

6. A method according to claim 5 wherein the coil has a substantially conical configuration.

7. A method according to claim 1 wherein the determining of the distribution of magnetic domains in step (e) comprises a numerical modelling method.

8. A method according to claim 7 wherein the numerical modelling method is selected from a finite element method, a boundary element method, a finite difference method and a finite volume method.

9. A method according to claim 1, wherein the material is a liquid including a magnetic compound.

10. A method according to claim 1, wherein the material comprises human blood.
